(19) United States
(12) Patent Application Publication
(10) Pub. No.: US 2025/0174589 A1
(43) Pub. Date: May 29, 2025

(54) PACKAGE STRUCTURE

(71) Applicant: Innolux Corporation, Miaoli County (TW)

(72) Inventors: Ying-Jen Chen, Miaoli County (TW); Wei-Lun Shieh, Miaoli County (TW)

(73) Assignee: Innolux Corporation, Miaoli County (TW)

(21) Appl. No.: 18/923,717

(22) Filed: Oct. 23, 2024

Related U.S. Application Data
(60) Provisional application No. 63/603,642, filed on Nov. 29, 2023.

(30) Foreign Application Priority Data
Jun. 26, 2024 (CN) 202410838760.3

(51) Int. Cl. H01L 23/00; H01L 23/31; H01L 25/065

(52) U.S. Cl. CPC H01L 24/16; H01L 23/3157; H01L 25/0657; H01L 2224/10125; H01L 2224/16146; H01L 2225/06513; H01L 2225/06541; H01L 2225/06565

(57) ABSTRACT

Disclosed is a package structure, including a first substrate, a second substrate, a bonding pad, a protective layer, and an air gap. The first substrate has a first surface and a second surface opposite to each other, and includes a first via extending from the first surface to the second surface. The second substrate is disposed on the first surface of the first substrate, has a third surface facing the first surface and a fourth surface opposite to the third surface, and includes a second via extending from the third surface to the fourth surface. The bonding pad is disposed between the first and second substrates and connected to the first and second vias. The protective layer is disposed between the first and second substrates, and surrounds the bonding pad. The air gap is disposed between the first and second substrates.

### CROSS-REFERENCE TO RELATED APPLICATION

This application claims the priority benefit of U.S. provisional application Ser. No. 63/603,642, filed on Nov. 29, 2023 and China application serial no. 202410838760.3, filed on Jun. 26, 2024. The entirety of each of the above-mentioned patent applications is hereby incorporated by reference herein and made a part of this specification.

### BACKGROUND

### Technical Field

The disclosure relates to a package structure.

### Description of Related Art

Generally, a package stacking structure involves stacking a package (e.g., a memory package) on another package (e.g., a logic package) through connection components such as solder balls. For example, the package stacking structure may be a memory package with a memory element stacked on a logic package with a logic element. However, the wiring density, spacing, or size of the memory package may not match the wiring density, spacing, or size of the logic package in some circumstances. Thus, disposing one or more additional substrates between the memory package and the logic package is regarded as a solution for the issue.

In a package structure formed by stacking multiple substrates, the coefficient of thermal expansion (CTE) of the bonding layer coated entirely between two adjacent substrates does not match the materials used for the substrates. Consequently, during other subsequent packaging processes, the thermal stress generated in high-temperature processes such as the reflow process can cause cracks in the conductive material embedded in the bonding layer and used to connect the signals of the two substrates, resulting in challenges in meeting the current or future requirements for package structure reliability.

### SUMMARY

The disclosure provides a package structure, which facilitates the improvement in package structure reliability.

According to an embodiment of the disclosure, a package structure includes a first substrate, a second substrate, a bonding pad, a protective layer, and an air gap. The first substrate has a first surface and a second surface opposite to each other, and includes a first via extending from the first surface to the second surface. The second substrate is disposed on the first surface of the first substrate, has a third surface facing the first surface and a fourth surface opposite to the third surface, and includes a second via extending from the third surface to the fourth surface. The bonding pad is disposed between the first substrate and the second substrate and connected to the first via and the second via. The protective layer is disposed between the first substrate and the second substrate and surrounds the bonding pad. The air gap is disposed between the first substrate and the second substrate.

According to another embodiment of the disclosure, a package structure includes a first glass substrate, a second glass substrate, multiple bonding pads, and at least one protective layer.

The first glass substrate includes multiple first through vias. The second glass substrate includes multiple second through vias. The bonding pads are disposed between the first glass substrate and the second glass substrate. Each of the bonding pads is overlapped and connected to the corresponding first through via and the corresponding second through via. The at least one protective layer is disposed between the first glass substrate and the second glass substrate and surrounds at least one of the bonding pads. The at least one protective layer and the at least one surrounded bonding pad define at least one first air gap between the first glass substrate and the second glass substrate.

Based on the above, in the embodiments of the disclosure, the air gap is disposed between the first substrate and the second substrate. Thus, during other packaging processes, the problem of cracks of the bonding pad between the first substrate and the second substrate, which is a result of mismatched coefficients of thermal expansion (CTE) and the materials used for the substrates, can be avoided, thereby facilitating the improvement in package structure reliability.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic diagram of a package structure according to an embodiment of the disclosure.

FIG. 2A is a top view schematic diagram of a bonding pad and a protective layer in an embodiment shown in FIG. 1.

FIG. 2B is a top view schematic diagram of a bonding pad and a protective layer in another embodiment shown in FIG. 1.

FIG. 2C is a top view schematic diagram of a bonding pad and a protective layer in still another embodiment shown in FIG. 1.

### DESCRIPTION OF THE EMBODIMENTS

The disclosure can be understood with reference to the following detailed description in conjunction with the accompanying drawings. It should be noted that, for ease of understanding by readers and for the concision of the illustration, multiple drawings in the disclosure only depict a part of the package structure, and certain elements in the drawings are not drawn according to actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words including “having” and “including” are open-ended words, and thus should be interpreted as meaning “including but not limited to.”

Directional terms mentioned herein, such as “up,” “down,” “front,” “rear,” “left,” “right,” and the like refer only to the directions of the drawings. Accordingly, the directional terms used are for illustration, and are not intended to limit the disclosure. It should be understood that when an element or film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping another element, the element or film layer at least partially overlaps the another element or film layer.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

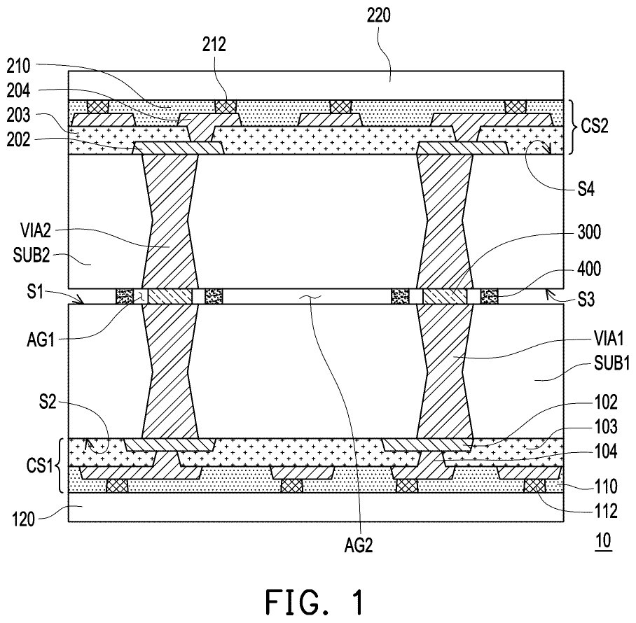

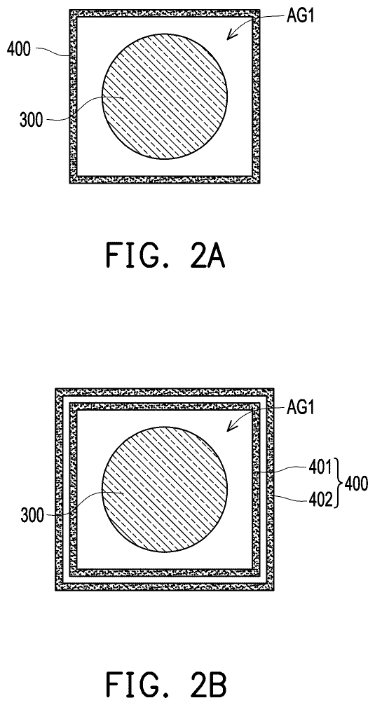

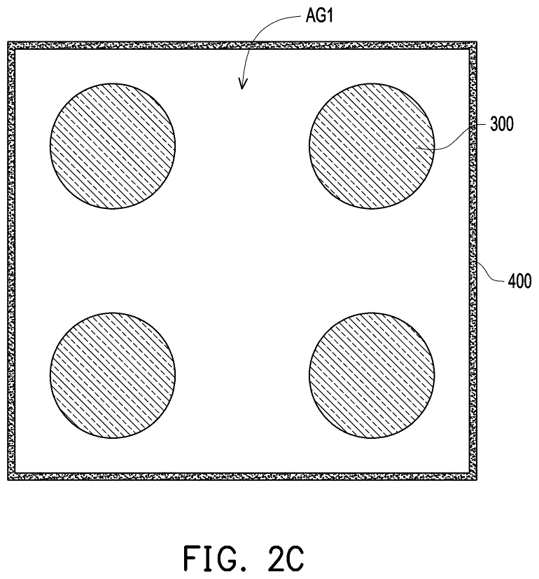

FIG. 1 is a cross-sectional schematic diagram of a package structure according to an embodiment of the disclosure. FIG. 2A is a top view schematic diagram of a bonding pad and a protective layer in an embodiment shown in FIG. 1. FIG. 2B is a top view schematic diagram of a bonding pad and a protective layer in another embodiment shown in FIG. 1. FIG. 2C is a top view schematic diagram of a bonding pad and a protective layer in still another embodiment shown in FIG. 1. A “top view direction” referred to herein may be, for example, a Z-direction.

Referring to FIG. 1, a package structure 10 includes a first substrate SUB1, a second substrate SUB2, a bonding pad 300, a protective layer 400, and an air gap AG1. In some embodiments, the package structure 10 may be included in electrical devices such as power modules, semiconductor devices, package devices, display devices, backlight modules, solar cells, sensing devices, automotive devices, high-frequency devices, antenna devices, lighting devices, splicing devices, or combinations thereof.

The first substrate SUB1 has a first surface S1 and a second surface S2 opposite to each other and includes a first via VIA1 extending from the first surface S1 to the second surface S2. In some embodiments, the material of the first substrate SUB1 may include glass, quartz, sapphire, ceramic, plastic, BT substrate, steel plate, other suitable substrate materials, or combinations thereof, but the disclosure is not limited thereto. In the disclosure, the first substrate may be a glass substrate, and the first via VIA1 may be a through glass via (TGV). The first via VIA1 may include conductive materials such as metal. Moreover, the conductive material may be, for example, a single-layer structure with a single type of metal, or a composite layer structure with multiple sub-layers, formed with different metals, stacked on each other. For example, the first via VIA1 may include a titanium layer (not shown) and a copper layer (not shown) stacked on the titanium layer, forming a composite layer structure. In some embodiments, the first via VIA1 may be formed through the following steps. First, a via hole (not shown) is formed in the first substrate SUB1. Next, a seed layer (not shown) is formed on a surface of the via hole. Then, through an electroplating process, the seed layer grows to form the first via VIA1 that fills the via hole.

The second substrate SUB1 is disposed on the first surface S1 of the first substrate SUB1, has a third surface S3 facing the first surface S1 and a fourth surface S4 opposite to the third surface S3, and includes a second via VIA2 extending from the third surface to the fourth surface.

In some embodiments, the material of the second substrate SUB2 may include glass, quartz, sapphire, ceramic, plastic, BT substrate, steel plate, other suitable substrate materials, or combinations thereof, but the disclosure is not limited thereto. In the disclosure, the second substrate may be a glass substrate, and the second via VIA2 may be a through glass via (TGV). The second via VIA2 may include conductive materials such as metal. Moreover, the conductive material may be, for example, a single-layer structure with a single type of metal, or a composite layer structure with multiple sub-layers, formed with different metals, stacked on each other. For example, the second via VIA2 may include a titanium layer (not shown) and a copper layer (not shown) stacked on the titanium layer, forming a composite layer structure. In some embodiments, the second via VIA2 may be formed through the same or similar steps as the first via VIA1, and the disclosure is not limited thereto.

In some embodiments, the package structure 10 may include a first circuit structure CS1 formed on the second surface S2 of the first substrate SUB1 and a second circuit structure CS2 formed on the fourth surface S4 of the second substrate SUB2.

In some embodiments, the first circuit structure CS1 may include a conductive layer 102 formed on the second surface S2 of the first substrate SUB1, an insulating layer 103 covering the conductive layer 102 and the second surface S2 of the first substrate SUB1, a wiring layer 104 formed on the insulating layer 103 and connected to the conductive layer 102, a solder mask layer 110 covering the wiring layer 104 and the insulating layer 103, and a pad 112 formed in the solder mask layer 110.

In some embodiments, the second circuit structure CS2 may include a conductive layer 202 formed on the fourth surface S4 of the second substrate SUB2, an insulating layer 203 covering the conductive layer 202 and the fourth surface S4 of the second substrate SUB2, a wiring layer 204 formed on the insulating layer 203 and connected to the conductive layer 202, a solder mask layer 210 covering the wiring layer 204 and the insulating layer 203, and a pad 212 formed in the solder mask layer 210.

Each of the conductive layer 102 and the conductive layer 202 may include and/or be at least one metal selected from Al, Ti, Cr, Fe, Co, Ni, Cu, Zn, Pd, Pt, Au, and Ag. In some embodiments, the conductive layer 102 and the conductive layer 202 may be respectively integrated in the processes through which the first via VIA1 and the second via VIA2 are formed.

The insulating layer 103 and the insulating layer 203 each includes organic or inorganic materials. Organic materials include polyimide (PI), poly-p-xylylene (also referred to as Parylene), benzocyclobutene (BCB), epoxy, polycarbonate (PC), polyethylene terephthalate (PET), polyethylene naphthalate (PEN), macromolecules, or other suitable organic materials, but the disclosure is not limited thereto. Inorganic materials include silicon dioxide, silicon nitride, silicon oxynitride, or other suitable inorganic materials, but the disclosure is not limited thereto. In some embodiments, the insulating layer 103 or the insulating layer 203 may be a single-layer structure or a multi-layer structure, but the disclosure is not limited thereto.

Each of the wiring layer 104 and the wiring layer 204 may include and/or be at least one metal selected from Al, Ti, Cr, Fe, Co, Ni, Cu, Zn, Pd, Pt, Au, and Ag. In some embodiments, the processes for forming the wiring layer 104 and the wiring layer 204 may include a damascene process. The damascene process includes the following steps. The insulating layer 103 and the insulating layer 203 is patterned to form openings therein. One or more conductive layers (e.g., a barrier layer and another conductive layer) are deposited (e.g., through CVD deposition) on the insulating layer 103 and the insulating layer 203. The one or more conductive layers are patterned to form the wiring layer 104 and the wiring layer 204.

The materials of the solder mask layer 110 and the solder mask layer 210 may include organic materials (e.g., polyimide-based resin, epoxy-based resin, or acrylic-based resin) or inorganic materials (e.g., silicon dioxide, silicon nitride, or silicon oxynitride). In some embodiments, each of the solder mask layer 110 and the solder mask layer 210 may be a single-layer structure or a multi-layer structure, but the disclosure is not limited thereto.

The pad 112 and the pad 212 may include and/or be at least one metal selected from Al, Ti, Cr, Fe, Co, Ni, Cu, Zn, Pd, Pt, Au, and Ag. In some embodiments, the pad 112 and the pad 212 may be formed through an electroless nickel immersion gold (ENIG) process. Based on this, the materials of the pad 112 and the pad 212 may include an alloy of gold and nickel, but the disclosure is not limited thereto.

In some embodiments, the package structure 10 includes a protective layer 120 formed on the first circuit structure CS1 and covering the pad 112. The package structure 10 also includes a protective layer 220 formed on the second circuit structure CS2 and covering the pad 212.

The materials of the protective layer 120 and the protective layer 220 may be, for example, suitable inorganic or organic materials, but the disclosure is not limited thereto. In some embodiments, the method of forming the protective layer 120 and the protective layer 220 may be performed through an attachment process, but the disclosure is not limited thereto.

The bonding pad 300 is disposed between the first substrate SUB1 and the second substrate SUB2 and connected to the first via VIA1 and the second via VIA2. The material of the bonding pad 300 may be, for example, a suitable conductive material (e.g., a conductive adhesive). In some embodiments, the bonding pad 300 directly contacts the first via VIA1 and the second via VIA2.

The protective layer 400 is disposed between the first substrate SUB1 and the second substrate SUB2 and surrounds the bonding pad 300. The material of the protective layer 400 may be a suitable insulating material, such as glass frit, optical adhesive, silicone, hot melt adhesive, AB adhesive, UV curing adhesive, polymer adhesive, resin, or combinations thereof, but the disclosure is not limited thereto.

In some embodiments, the air gap AG1 is disposed between the first substrate SUB1 and the second substrate SUB2. In some embodiments, the bonding pad 300 directly contacts the first via VIA1 and the second via VIA2, and defines the air gap AG1 with the protective layer 400. Since the air gap AG1 is disposed at a linking site between the first substrate SUB1 and the second substrate SUB2 (e.g., a location of the bonding pad 300 connected to the first via VIA1 and the second via VIA2), when other packaging processes are performed, the bonding pad 300 does not crack due to mismatched coefficients of thermal expansion (CTE) of the materials used for the first substrate SUB1 and the second substrate SUB2. Thus, a signal connection between the first substrate SUB1 and the second substrate SUB2 is not affected, thereby facilitating the improvement in the reliability of the package structure 10.

In some embodiments, as shown in FIGS. 2A to 2C, the protective layer 400 surrounds the bonding pad 300 in a closed-loop manner. This enables the protective layer 400 to prevent external moisture from intruding into the linking site between the first substrate SUB1 and the second substrate SUB2, thereby facilitating the improvement in the connection reliability between the bonding pad 300 and the first via VIA1 and the second via VIA2.

In some embodiments, as shown in FIG. 2B, the protective layer 400 includes a first guard ring 401 surrounding the bonding pad 300 and a second guard ring 402 surrounding the first guard ring 401. This further prevents external moisture from intruding into the linking site between the first substrate SUB1 and the second substrate SUB2. In some embodiments, as shown in FIG. 2A, a single protective layer 400 surrounds a corresponding bonding pad 300. In some alternative embodiments, as shown in FIG. 2C, the protective layer 400 surrounds multiple bonding pads 300.

The bonding pads 300 shown in FIGS. 2A to 2C are illustrated in a shape corresponding to the first via VIA1 and the second via VIA2 (e.g., a circular shape), but the disclosure is not limited to thereto. Shapes different from the first via VIA1 and the second via VIA2 (e.g., a rectangular shape) may also be adopted for the bonding pads 300. The protective layer 400 shown in FIGS. 2A to 2C surrounds the bonding pads 300 in a rectangular manner, but the disclosure is not limited to thereto. The protective layer 400 may also surround the bonding pads 300 in other manners, such as an annular manner.

In some embodiments, a horizontal area of the protective layer 400 is less than 50% of a horizontal area of the first substrate SUB1 or the second substrate SUB2.

In some embodiments, a package structure 10 includes a first glass substrate SUB1, a second glass substrate SUB2, multiple bonding pads 300, and at least one protective layer 400. The first glass substrate SUB1 includes multiple first through vias VIA1. The second glass substrate SUB2 includes multiple second through vias VIA2. The bonding pads 300 are disposed between the first glass substrate SUB1 and the second glass substrate SUB2. Each of the bonding pads 300 is overlapped and connected to the corresponding first through via VIA1 and the corresponding second through via VIA2. The at least one protective layer 400 is disposed between the first glass substrate SUB1 and the second glass substrate SUB2 and surrounds at least one of the bonding pads 300. The at least one protective layer 400 and the at least one surrounded bonding pad 300 define at least one first air gap AG1 between the first glass substrate SUB1 and the second glass substrate SUB2.

In some embodiments, the at least one protective layer 400 includes multiple protective layers 400, and a second air gap AG2 between the first glass substrate SUB1 and the second glass substrate SUB2 may be formed between the protective layers 400, wherein the second air gap AG2 does not communicate with the first air gap AG1. In some embodiments, the protective layer 400 surrounds at least some of the bonding pads 300 (as shown in FIG. 2C). In some embodiments, a total horizontal area of the protective layers 400 is less than 50% of the horizontal area of the first substrate SUB1 or the second substrate SUB2.

In summary, in the embodiments of the disclosure, since the air gap is disposed at the linking site between the first substrate and the second substrate (i.e., the location of the bonding pad connected to the first via and the second via), when other packaging processes are performed, the bonding pad does not crack due to mismatched coefficients of thermal expansion (CTE) of the materials used for the first substrate and the second substrate. Thus, the signal connection between the first substrate and the second substrate is not affected, thereby facilitating the improvement in package structure reliability. In some embodiments, the protective layer 400 surrounding the bonding pad 300 further prevent external moisture from intruding into the linking site between the first substrate and the second substrate, thereby facilitating the improvement in the connection reliability between the bonding pad and the first via and the second via.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. A package structure, comprising:
a first substrate, having a first surface and a second surface opposite to each other, and comprising a first via extending from the first surface to the second surface;
a second substrate, disposed on the first surface of the first substrate and having a third surface facing the first surface and a fourth surface opposite to the third surface, further comprising a second via extending from the third surface to the fourth surface;
a bonding pad, disposed between the first substrate and the second substrate and connected to the first via and the second via;
a protective layer, disposed between the first substrate and the second substrate and surrounding the bonding pad; and
an air gap, disposed between the first substrate and the second substrate.

2. The package structure according to claim 1, wherein each of the first substrate and the second substrate is a glass substrate.

3. The package structure according to claim 1, wherein the bonding pad directly contacts the first via and the second via and defines the air gap with the protective layer.

4. The package structure according to claim 3, wherein an area of the protective layer contacting the first substrate or the second substrate is less than an area of the air gap contacting the first substrate or the second substrate.

5. The package structure according to claim 3, wherein the first via or the second via comprises a surface exposed by the air gap.

6. The package structure according to claim 1, wherein the protective layer surrounds the bonding pad in a closed-loop manner.

7. The package structure according to claim 1, wherein the protective layer comprises a first guard ring surrounding the bonding pad and a second guard ring surrounding the first guard ring.

8. The package structure according to claim 1, wherein a horizontal area of the protective layer is less than 50% of a horizontal area of the first substrate or the second substrate.

9. The package structure according to claim 1, further comprising:
a first circuit structure, disposed on the second surface of the first substrate and electrically connected to the first via; and
a second circuit structure, disposed on the fourth surface of the second substrate and electrically connected to the second via.

10. The package structure according to claim 9, further comprising:
a first protective film, covering the first circuit structure; and
a second protective film, covering the second circuit structure.

11. A package structure, comprising:
a first glass substrate, comprising a plurality of first through vias;
a second glass substrate, comprising a plurality of second through vias;
a plurality of bonding pads, disposed between the first glass substrate and the second glass substrate, wherein each of the plurality of bonding pads is overlapped and connected to a corresponding one of the plurality of first through vias and a corresponding one of the plurality of second through vias; and
at least one protective layer, disposed between the first glass substrate and the second glass substrate and surrounding at least one of the plurality of bonding pads, wherein the at least one protective layer and the at least one surrounded bonding pad define at least one first air gap between the first glass substrate and the second glass substrate.

12. The package structure according to claim 11, wherein an area of the at least one protective layer contacting the first glass substrate or the second glass substrate is less than an area of the at least one first air gap contacting the first glass substrate or the second glass substrate.

13. The package structure according to claim 11, wherein the at least one protective layer surrounds the at least one of the plurality of bonding pads in a closed-loop manner.

14. The package structure according to claim 11, wherein the at least one protective layer surrounds at least some of the plurality of bonding pads.

15. The package structure according to claim 11, wherein the at least one protective layer comprises a first guard ring surrounding the at least one of the plurality of bonding pads and a second guard ring surrounding the first guard ring.

16. The package structure according to claim 11, wherein the plurality of first through vias or the plurality of second through vias comprise a surface exposed by the at least one first air gap.

17. The package structure according to claim 11, wherein the at least one protective layer comprises a plurality of protective layers, and a second air gap between the first glass substrate and the second glass substrate is formed between the plurality of protective layers, wherein the second air gap does not communicate with the at least one first air gap.

18. The package structure according to claim 17, wherein a total horizontal area of the plurality of protective layers is less than 50% of a horizontal area of the first glass substrate or the second glass substrate.

19. The package structure according to claim 17, wherein each of the plurality of protective layers surrounds the corresponding at least one of the plurality of bonding pads.

20. The package structure according to claim 17, wherein the second air gap does not expose the plurality of first through vias or the plurality of second through vias.
